(19) United States
(12) Patent Application Publication
(10) Pub. No.: US 2026/0190837 A1
(43) Pub. Date: Jul. 2, 2026

(54) DISPLAY DEVICE

(71) Applicant: LG Display Co., Ltd., Seoul (KR)

(72) Inventors: Sung Jin LEE, Paju-si (KR); Dong Chae SHIN, Paju-si (KR)

(73) Assignee: LG Display Co., Ltd., Seoul (KR)

(21) Appl. No.: 19/429,018

(22) Filed: Dec. 22, 2025

(30) Foreign Application Priority Data
Dec. 30, 2024 (KR) 10-2024-0200937

(51) Int. Cl. H10K 59/80; H10K 59/122; H10K 59/131; H10K 59/40

(52) U.S. Cl. CPC H10K 59/8792; H10K 59/122; H10K 59/131; H10K 59/40

(57) ABSTRACT

A display device includes a substrate including an active area and a non-active area outside the active area; a sensor disposed under a portion of the active area of the substrate; a light-emitting element on the active area of the substrate, the light-emitting element including a first electrode, an intermediate layer on the first electrode and including an emission layer, and a second electrode on the intermediate layer; a light-shielding bank on the first electrode and defining an emission area of the light-emitting element; and a metal block extending vertically and positioned between the substrate and the light-emitting element in a cross-sectional view, the metal block being disposed adjacent to the sensor and including two or more metal layers.

This application claims the benefit of Korean Patent Application No. 10-2024-0200937, filed on Dec. 30, 2024, which is hereby incorporated by reference as if fully set forth herein.

### BACKGROUND

### Field of the Disclosure

The present disclosure relates to a display device having a sensor in an active area, which can secure element stability against external light and reduce wiring resistance.

### Discussion of the Related Art

A display device that displays an image is applied not only to devices with a display, such as TVs, monitors, smartphones, tablets, and laptop computers, but also to such devices as vehicle panels, display glass, wristwatches, and home appliances.

A display device includes a plurality of pixels to display an image and has transistors to control the operation of each pixel.

Among various display devices, a display device that does not have a separate light source and includes light-emitting elements inside a display panel for compactness and clear color display is considered a competitive application.

### SUMMARY

Accordingly, the present disclosure is directed to a display device that substantially obviates one or more problems due to limitations and disadvantages of the related art.

A display device may be equipped with a sensor for various purposes. As the integration of the display device increases, the sensor can be disposed to overlap or be adjacent to an active area.

An aspect of the present disclosure is to provide a display device for preventing or blocking light received by a sensor from being incident on the side and affecting elements, such as transistors, disposed on a substrate.

Another aspect of the present disclosure is to provide a display device for preventing or suppressing external light reflection using components around an emission area without having a separate polarizing plate.

Yet another aspect of the present disclosure is to provide a display device for reducing the resistance of wiring lines.

An additional aspect of the present disclosure is to provide a display device for maintaining transmittance of a transmissive area provided in a sensor and improving the reliability of elements around the transmissive area.

Another aspect of the present disclosure is to provide a display device capable of reducing production energy for producing a display device without increasing, or by reducing, the number of layers, and decreasing the use of hazardous production materials or regulated substances, thereby achieving an eco-friendly display device advantageous for recycling.

Additional advantages, aspects, and features of the present disclosure will be set forth in part in the description which follows and in part will become apparent to those having ordinary skill in the art upon examination of the following or may be learned from practice of the present disclosure. The aspects and other advantages of the present disclosure may be realized and attained by the structure particularly pointed out in the written description and claims hereof as well as the appended drawings.

To achieve these objects and other advantages and in accordance with the purpose of the disclosure, as embodied and broadly described herein, a display device according to one or more example embodiments of the present disclosure includes a sensor in an active area. A metal block is provided around the sensor to prevent or block light received by the sensor from being transmitted laterally and affecting elements around the sensor.

In another aspect, a display device according to one or more example embodiments of the present disclosure includes a substrate including an active area and a non-active area outside the active area; a sensor disposed under a portion of the active area of the substrate; a light-emitting element on the active area of the substrate, the light-emitting element including a first electrode, an intermediate layer on the first electrode and including an emission layer, and a second electrode on the intermediate layer; a light-shielding bank on the first electrode and defining an emission area of the light-emitting element; and a metal block extending vertically and positioned between the substrate and the light-emitting element in a cross-sectional view, the metal block being disposed adjacent to the sensor and including two or more metal layers.

It is to be understood that both the foregoing general description and the following detailed description of the present disclosure are by way of example and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain principles of the present disclosure. In the drawings:

FIG. 1 is a plan view showing a display device according to one or more example embodiments of the present disclosure;

FIG. 2 is a circuit diagram showing an example subpixel of FIG. 1;

FIG. 3 is a plan view showing a portion of first sensor part A in the example display device of FIG. 1 according to a first example embodiment of the present disclosure;

FIG. 4 is a cross-sectional view taken along line I-I′ in FIG. 3;

FIG. 5 is a plan view showing a portion of first sensor part A in the example display device of FIG. 1 according to a second example embodiment of the present disclosure;

FIG. 6 is a plan view showing a portion of first sensor part A in the example display device of FIG. 1 according to a third example embodiment of the present disclosure;

FIGS. 7A to 7D are cross-sectional views showing various example embodiments of a metal block;

FIG. 8 is a plan view showing a portion of second sensor part B in the example display device of FIG. 1 according to a fourth example embodiment of the present disclosure;

FIG. 9 is a cross-sectional view taken along line II-II′ in FIG. 8;

FIG. 10 is a plan view showing an example of a first metal layer in area C of the example display device of FIG. 8;

FIG. 11 is a plan view showing an example of a first hole and a second metal layer in area C of the example display device of FIG. 8; and

FIG. 12 is a plan view showing an example of the second hole and a third metal layer in area C of the example display device of FIG. 8.

### DETAILED DESCRIPTION

The advantages and features of the present disclosure and the way of attaining the same will become apparent with reference to example embodiments described below in detail in conjunction with the accompanying drawings. The present disclosure, however, is not limited to the example embodiments disclosed hereinafter and may be embodied in many different forms. Rather, these example embodiments are provided so that the present disclosure will be more through and complete and will more fully convey the scope to those skilled in the art. The protected scope of the present disclosure may be defined by the claims and their equivalents.

The same or extremely similar elements are designated by the same reference numerals throughout the specification, unless otherwise specified, and in the drawings, the lengths and thickness of layers and regions may be exaggerated for convenience. The scale of the components shown in the drawings may be different from the actual scale, and is not limited to the scale shown in the drawings.

It should be understood that, where a certain element (or a region, a layer, or a portion) is referred to as being “on,” “connected to,” or “combined with” another element, the element may be directly connected/combined to/with the other element, or a third element may be interposed therebetween.

“And/or” includes any combination of one or more of the associated components.

While terms, such as “first,” “second,” etc., may be used to describe various components, such components are not to be limited by the above terms. The above terms are used only to refer to one component separately from another. In addition, terms particularly defined in consideration of construction and operation of the embodiments are used only to describe the example embodiments and do not define the scope of the embodiments.

In the description of the example embodiments, it should be understood that, where an element is referred to as being formed “on” or “under” another element, it can be directly “on” or “under” the other element or be indirectly formed with intervening elements therebetween. It should also be understood that, where an element is referred to as being “on” or “under,” “under the element” as well as “on the element” can be included based on the element.

It should be further understood that the terms “comprise” and “include” specify the presence of stated features, integers, steps, operations, elements, components, and/or combinations thereof, but do not preclude the presence or addition of one or more other features, integers, steps, operations, elements, components, and/or combinations.

The respective features of the various embodiments of the present disclosure may be partially or wholly coupled to and combined with each other, and various technical linkage and driving thereof are possible. These various embodiments may be performed independently of each other or may be performed in association with each other.

Hereinafter, a display device according to various example embodiments of the present disclosure will be described with reference to the attached drawings.

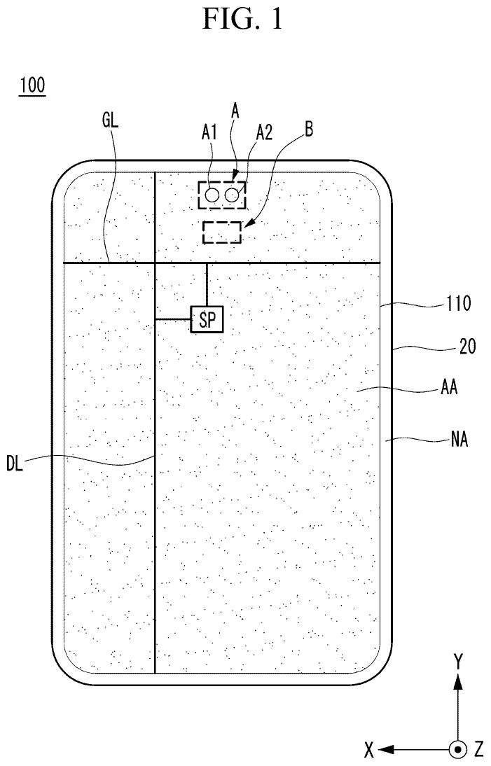

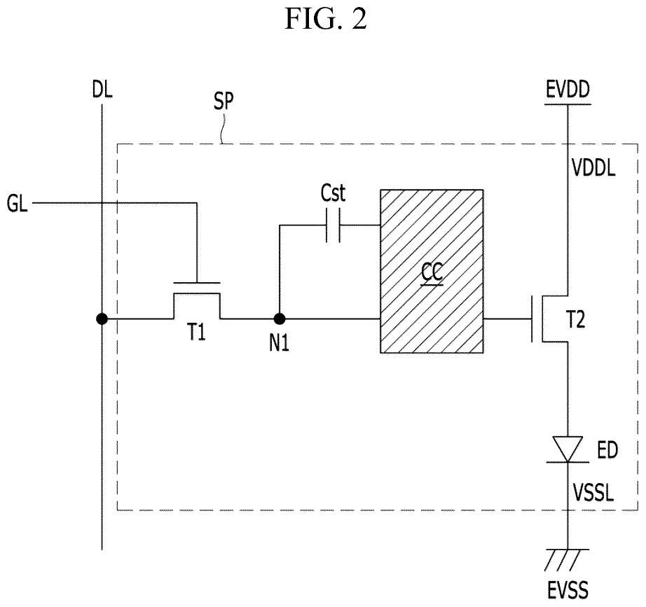

FIG. 1 is a plan view showing a display device according to one or more example embodiments of the present disclosure. FIG. 2 is a circuit diagram showing an example subpixel of FIG. 1.

As illustrated in FIG. 1, a display device 100 according to an example embodiment of the present disclosure includes a display panel 110 including an active area AA and a non-active area NA and a cover member 20 provided on the display panel 110.

The cover member 20 is disposed on the display panel 110 to cover the front of the display panel 110 and protect the display panel 110 from external impact. The edge of the cover member 20 may have a curved portion or a curved surface portion that is bent in the direction (e.g., the Z-axis direction) of the back surface of the display device 100. Accordingly, the cover member 20 can cover the side area of the display panel 110, and the display panel 110 can be protected from external impact not only on the front but also on the side of the display device 100.

The active area AA of the display device 100 is an area for displaying an image, and an area other than the active area AA is a non-active area NA. The active area AA and the non-active area NA of the display device 100 is applied equally to the display panel 110.

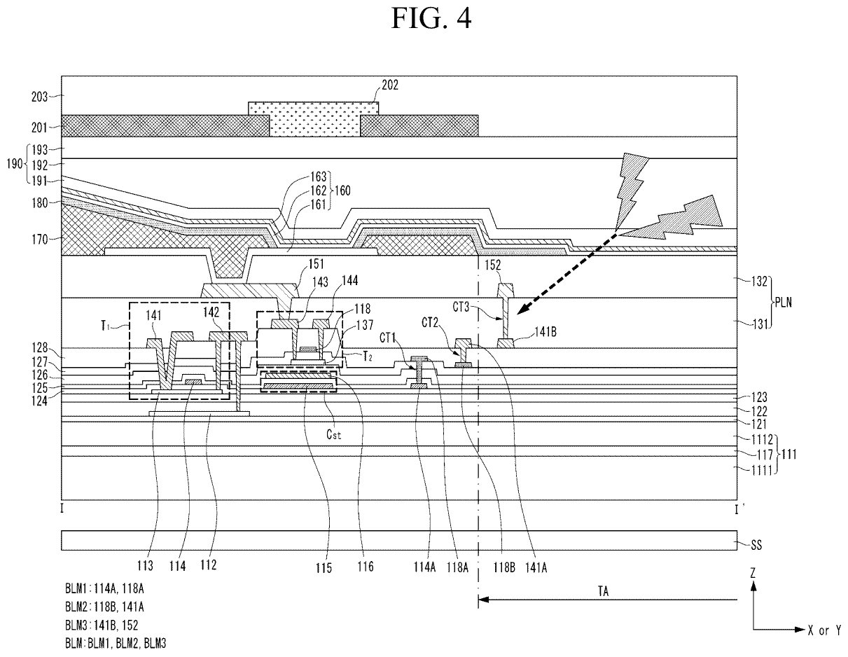

The display device 100 includes a substrate (111 in FIG. 4) having both the active area AA and the non-active area NA. In the active area AA on the substrate, a plurality of data lines DL extending in a first direction (e.g., the Y-axis direction) and a plurality of gate lines GL extending in a second direction (e.g., the X-axis direction) intersecting the first direction may be disposed.

Subpixels SP may be disposed at intersections of the data lines DL and the scan lines SL. One subpixel SP can be defined as an emission area. However, in the embodiments of the present disclosure, the emission area is not necessarily limited to the region defined by an intersection of a data line DL and a gate line GL. That is, at least some emission areas may intersect data lines DL and/or gate lines GL.

The subpixel SP is disposed between a gate line GL and a data line DL that intersect each other, as shown in FIG. 2, and may include a first transistor T1, a second transistor T2, a storage capacitor Cst, a compensation circuit CC, and a light-emitting element ED.

For example, the first transistor T1 may be a switching transistor, and the second transistor T2 may be a driving transistor.

Each of the first transistor T1 and the second transistor T2 may include an active layer, a gate electrode, and first and second source-drain electrodes. The active layer of at least one of the first and second transistors T1 and T2 may include at least one of amorphous silicon, crystalline silicon, or an oxide semiconductor. The active layer of at least one of the first and second transistors T1 and T2 may include an oxide semiconductor. For example, the oxide semiconductor may include an oxide semiconductor material, such as IGZO (Indium-Gallium-Zinc-Oxide).

The first transistor T1 is electrically connected to the data line DL and electrically connected to a first node N1. The gate electrode of the first transistor T1 is electrically connected to the gate line GL. The first transistor T1 transmits a data signal supplied through the data line DL to the first node N1 in response to a scan signal supplied through the gate line GL.

The storage capacitor Cst is electrically connected to the first node N1 and is charged with a voltage applied to the first node N1.

The second transistor T2 receives a high-level driving voltage EVDD and is electrically connected to the first electrode (e.g., anode) of the light-emitting element ED. The second transistor T2 can control the amount of driving current flowing through the light-emitting element ED in response to a voltage applied to the gate electrode thereof. The high-level driving voltage EVDD is applied to the second transistor T2 through a first power voltage line VDDL.

The light-emitting element ED emits light corresponding to the driving current supplied from the second transistor T2. The light-emitting element ED may output light corresponding to one of red, green, blue, and white.

The light-emitting element ED includes a first electrode, an intermediate layer disposed on the first electrode, and a second electrode. The second electrode of the light-emitting element ED may be connected to a second power voltage line VSSL through which a low-level driving voltage EVSS is supplied. The second power voltage line VSSL may be provided in the non-active area NA and connected to the second electrode. In some cases, the second power voltage line VSSL may also be provided in the active area AA to supply the low-level driving voltage EVSS to each subpixel SP or a plurality of subpixels SP and to make the voltages of the second electrodes in subpixels uniform.

The intermediate layer includes an emission layer and various functional layers, and may emit light of the same color for each pixel, such as white light, or may emit lights of different colors for respective subpixels SP, such as red, green, or blue light. The functional layers may include a hole injection layer, a hole transport layer, an electron transport layer, an electron injection layer, and a charge generation layer. The intermediate layer may include a plurality of stacks, and the plurality of stacks may include a charge generation layer between adjacent stacks to facilitate supply of holes and electrons between the adjacent stacks. Each of the plurality of stacks may include at least one emission layer, a hole transport layer, and an electron transport layer.

The first electrode may serve as an anode, and the second electrode may serve as a cathode. The light-emitting element ED is substantially the same as a light-emitting element (160 in FIG. 4) which will be described below.

The compensation circuit CC may be provided in the subpixel SP to compensate for the threshold voltage of the second transistor T2. The compensation circuit CC may be composed of one or more transistors. The compensation circuit CC may include one or more transistors and a capacitor, and may be configured in various manners depending on the compensation method. A pixel including the compensation circuit CC may have various structures, such as 3T1C, 4T2C, 5T2C, 6T1C, 6T2C, 7T1C, and 7T2C. For example, a plurality of transistors may be electrically connected between the second transistor T2 and the light-emitting element ED.

In FIG. 2, the second transistor T2 and the light-emitting element ED are directly connected to each other, but the embodiments of the present disclosure are not limited thereto. Depending on the form of the compensation circuit CC, there may be another transistor or compensation capacitor between the light-emitting element ED and the second transistor T2 that generates a driving current.

The display device 100 of the example embodiments of the present disclosure includes sensor parts A and B in the active area AA.

The first sensor part A may include a plurality of sensors A1 and A2. Examples of the sensors A1 and A2 may include, for example, an image sensor or a camera that receives or captures image information, an infrared sensor that senses infrared light, and a fingerprint recognition sensor that senses fingerprint information. In FIG. 1, the sensors A1 and A2 may have a circular shape, for example, but the shape of the sensors A1 and A2 is not necessarily limited thereto. The sensors A1 and A2 may have a polygonal or oval shape. A light receiving area of each of the sensors A1 and A2 may be limited to a portion of the area occupied by each sensor.

The second sensor part B may be disposed adjacent to the first sensor part A or may be disposed independently. The second sensor part B may include an RGB sensor that detects the color spectrum of ambient light and/or an illuminance sensor that detects the brightness of ambient light. The second sensor part B may be used to automatically adjust the brightness and color of the display device 100 by detecting the color spectrum and brightness of ambient light.

The first and second sensor parts A and B may be provided under the display panel 110 and overlap a portion of the active area AA of the display panel 110.

Hereinafter, the specific example configurations of the first and second sensor parts A and B will be described.

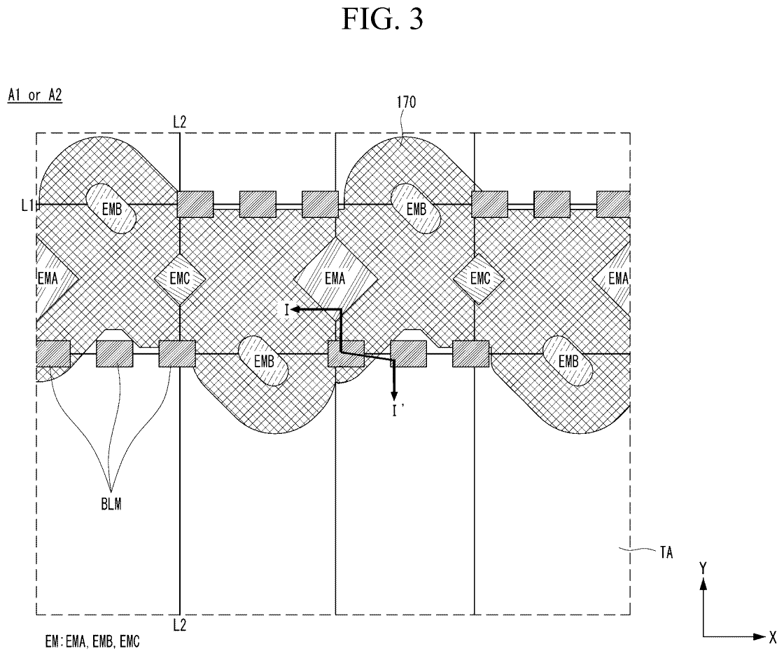

FIG. 3 is a plan view showing a portion of the first sensor part A (sensor A1 or A2) in the example display device according to a first example embodiment of the present disclosure. FIG. 4 is a cross-sectional view taken along line I-I′ in FIG. 3.

As shown in FIG. 3, the first sensor part A is an area that displays an image and receives image information. Therefore, the first sensor part A may include emission areas EM (EMA, EMB, and EMC) for displaying an image, and a transmissive area TA to increase light reception efficiency of an area where light is sensed. The transmissive area TA is positioned such that it does not overlap wiring lines L1 and L2 and a light-shielding bank 170, and can increase the light reception efficiency when light is sensed through the transmissive area TA.

The emission areas EM (EMA, EMB, and EMC) may be positioned to overlap the first and second wiring lines L1 and L2 that intersect each other.

The first wiring lines L1 disposed in the second direction (e.g., X-axis direction) in the subpixel SP may be gate lines (e.g., scan lines GL in FIG. 2). In some cases, depending on the number and types of transistors provided in the subpixel, additional gate lines and/or emission control lines may be further provided in the second direction (X-axis direction) in the subpixel SP in addition to the illustrated gate lines. At least some of the first wiring lines L1 may overlap some emission areas EM (e.g., EMB in FIG. 3) in the second direction.

The second wiring lines L2 disposed in the first direction (e.g., Y-axis direction) in the subpixel SP may be data lines (e.g., DL in FIG. 2).

In some cases, the first power voltage line VDDL through which the high-level voltage is supplied and/or the second power voltage line VSSL through which the low-level voltage is supplied may be additionally included in the subpixel SP in the form of the first wiring lines L1 or the second wiring lines L2 in at least one of the first direction (Y-axis direction) and the second direction (X-axis direction).

The gate lines GL, the data lines DL, the first power voltage line VDDL, and the second power voltage line VSSL as the first wiring lines L1 or the second wiring lines L2 may partially overlap with the emission areas EM (EMA, EMB, and EMC) in the second direction (X-axis direction) or the first direction (Y-axis direction).

The emission areas EM (EMA, EMB, and EMC) may be defined as openings of the light-shielding bank 170. The openings of the light-shielding bank 170 may serve as emission areas.

Different emission areas EMA, EMB, and EMC can emit lights of different colors.

For example, the first emission area EMA can emit blue light, the second emission area EMB can emit green light, and the third emission area EMC can emit red light. The areas of the first to third emission areas EMA, EMB, and EMC can be adjusted differently depending on the luminous efficacy. Since a material emitting light of a shorter wavelength has lower luminous efficacy, the area of the first emission area EMA can be greater than those of the second and third emission areas EMB and EMC. Since the contribution of green light emission is high when expressing white, the second emission area EMB may be arranged in a higher density than the first and third emission areas EMA and EMC.

The relative arrangement densities of the emission areas EM (EMA, EMB, and EMC) and the shapes of the emission areas EM (EMA, EMB, and EMC) may be the same throughout the active area AA including the first sensor part A (A1 and A2). However, the overall area of the emission areas may be decreased, and the area of the transmissive area TA may be increased in the first sensor part A (A1 and A2).

The light-shielding bank 170 may be disposed between the emission areas EMA, EMB, and EMC and between the emission areas EM (EMA, EMB, and EMC) and the transmissive areas TA.

The transmissive areas TA do not overlap the first and second wiring lines L1 and L2 and thus can improve the transmission efficiency of the sensors A1 and A2 in the first sensor part A.

The light-shielding bank 170 may include, for example, a light-shielding organic insulating material. The light-shielding organic insulating material is a material that absorbs light and includes a material that at least absorbs light in the visible spectrum.

The light-shielding bank 170 may be disposed adjacent to the emission areas EMA, EMB, and EMC in a region where the emission areas EMA, EMB, and EMC in the first sensor part A (A1 or A2) are densely disposed.

FIG. 3 illustrates an example in which the first emission area EMA and the third emission area EMC have a rhombus shape, and the second emission area EMB has a diagonally elongated oval shape. This is an example, and the emission areas EM may have various other shapes, such as a circular shape, a triangular shape, a polygonal shape, and a shape with curved corners and straight sides.

At least parts of the first and second wiring lines L1 and L2 may overlap the light-shielding bank 170.

As shown in FIG. 3, where the transmissive areas TA are densely disposed in the second direction (X-axis direction) or the first direction (Y-axis direction), the first wiring lines L1 or the second wiring lines L2 between the densely disposed transmissive areas TA may not overlap entirely or partly with the light-shielding bank 170. The first wiring lines L1 or the second wiring lines L2 may be disposed between adjacent transmissive areas TA and may partition the transmissive areas TA. The first and second wiring lines L1 and L2 are made of a light-shielding metal, and have widths less than the width of the light-shielding bank 170 and thus may not be visible even if they are disposed between the transmissive areas TA.

The display device according to an example embodiment of the present disclosure shown in FIG. 3 includes metal blocks BLM disposed between the transmissive areas TA and the emission areas EM (EMA, EMB, and EMC).

The metal blocks BLM may be arranged in a distributed manner along the edges of the transmissive areas TA. The metal blocks BLM may be arranged in in the row direction or the second direction (X-axis direction). As shown in FIG. 3, at least some of the metal blocks BLM may be disposed to overlap the light-shielding bank 170, and may be disposed in the same row as metal blocks BLM that overlap the light-shielding bank 170 in the second direction or in an adjacent row.

The light-shielding bank 170 is disposed to surround the emission areas EM (EMA, EMB, and EMC), and thus may have an edge shape similar to the curved or straight edge shapes of the emission areas in a region adjacent to the transmissive area TA.

Components on the substrate 111 will be described with reference to FIG. 4.

As shown in FIG. 4, a sensor SS may be provided under the substrate 111 corresponding to the first sensor part A (A1 or A2).

The metal blocks BLM (BLM1, BLM2, and BLM3) may be positioned between the substrate 111 and the light-emitting element 160. In addition, the metal blocks BLM (BLM1, BLM2, and BLM3) may be positioned between the substrate 111 and the light-shielding bank 170. The metal blocks BLM (BLM1, BLM2, and BLM3) include two or more metal layers and disposed to overlap the sensor SS or disposed adjacent to the sensor SS.

The light-emitting element 160 includes a first electrode 161, intermediate layers 162, and a second electrode 163. At least some of the intermediate layers 162 and the second electrode 163 may be disposed over the entire active area AA and may overlap the metal blocks BLM (BLM1, BLM2, and BLM3).

FIG. 4 shows that first to third metal blocks BLM1, BLM2, and BLM3 having different layer structures form one metal block BLM. This is an example, and the metal block BLM may be formed using only one of the first to third metal blocks BLM1, BLM2, and BLM3 or using two metal blocks selected from the first to third metal blocks BLM1, BLM2, and BLM3.

The first to third metal blocks BLM1, BLM2, and BLM3 may include holes CT1, CT2, and CT3 formed between lower metal layers 114A, 118B, and 141B and upper metal layers 118A, 141A, and 152 and filled with the materials of upper metal layers 118A, 141A, and 152, respectively.

Accordingly, when light propagates to the sensor, metal blocks adjacent to the light propagation path can block the light from being transmitted laterally, thereby preventing components, such as transistors and others, disposed on the substrate from being affected by reception of light by the sensor.

The materials of the upper metal layers 118A, 141A, and 152 filled respectively in the holes CT1, CT2, and CT3 may come into contact with insulating layers 125/126/127, 128, or 131 disposed between the lower metal layers 114A, 118B, and 141B and the upper metal layers 118A, 141A, and 152.

The materials of the upper metal layers 118A, 141A, and 152 filled in the holes CT1, CT2, and CT3 serve to block light transmitted laterally from the insulating layers 125, 126, 127, 128, and 131.

In the display device of example embodiments of the present disclosure, the holes CT1, CT2, and CT3 filled with the upper metal layers are used to block side light, and in some cases, the holes CT1, CT2, and CT3 may not be directly electrically connected to the lower metal layers. In addition, even if the upper metal layers are connected to the lower metal layers through the holes CT1, CT2, and CT3, the upper metal layers 118A, 141A, and 152 and the lower metal layers 114A, 118B, and 141B are provided in an island form and thus may not have an electrical connection with an external device or an electrical flow to or from any other components on the substrate.

The upper metal layers 118A, 141A, and 152 and the lower metal layers 114A, 118B, and 141B are each provided in an island form and may be in a floating state without having an electrical connection with an external device or with any other components on the substrate. The metal block BLM may be disposed in a floating state on the substrate 111.

The widths of the holes CT1, CT2, and CT3 may be less than the widths of the lower metal layers 114A, 118B, and 141B or the widths of the upper metal layers 118A, 141A, and 152 positioned on the insulating layers 127, 128, and 131. Even though the holes CT1, CT2, and CT3 are narrow, light can be blocked by long vertical paths of the metal blocks BLM1, BLM2, and BLM3 formed to penetrate the insulating layers 125/126/127, 128 or 131 having a certain thickness or more. Therefore, even if the areas of the metal blocks BLM1, BLM2, and BLM3 in the horizontal plane are not increased, the metal blocks BLM (BLM1, BLM2, and BLM3) can prevent or block lateral transmission of side light through the vertical paths in the holes CT1, CT2, and CT3. This means that, even if the area of the transmissive area TA of the first sensor part A is not reduced or adjusted, lateral transmission of side light can be blocked by the metal blocks BLM provided around the transmissive area TA of the first sensor part A.

The example configuration of the first sensor part A and the example configuration of the subpixel SP outside the first sensor part A are compared and described with reference to FIG. 4.

A plurality of subpixels SP is provided in the active area AA of the substrate 111, and a plurality of subpixels SP may also be included in the first sensor part A.

The substrate 111 may be made of a flexible material and can be easily removed when a laser is radiated thereto to form a hole H. For example, the substrate 111 may be formed of first and second organic films 1111 and 1112 that overlap each other with an inorganic interlayer insulating layer 117 interposed therebetween. The inorganic interlayer insulating layer 117 may serve to block transfer of moisture or impurities between the first and second organic films 1111 and 1112. The inorganic interlayer insulating layer 117 is formed on the first organic film 1111 and may be partially patterned. The inorganic interlayer insulating layer 117 may include at least one of a silicon nitride layer, a silicon oxide layer, and a silicon oxynitride layer.

The first and second organic films 1111 and 1112 may include, for example, polyimide. In addition to polyimide, the first and second organic films 1111 and 1112 may include different organic films.

The substrate 111 may include a polyethylene terephthalate (PET) film one of the first and second organic films 1111 and 1112 and a polyimide film as the other.

As another example, the substrate 111 may include thin glass having flexibility.

The substrate 111 serves to support and protect components of the display device placed thereon.

A plurality of laminated insulating layers 120 (121, 122, 123, 124, 125, 126, 127, and 128) and planarization layers 131 and 132 are disposed on the active area AA and the non-active area NA of the substrate 111 such that light-shielding patterns 112 and 116 of the transistors T1 and T2 are insulated from active layers 113 and 137, the active layers 113 and 137 are insulated from gate electrodes 114 and 118, the gate electrodes 114 and 118 are insulated from source-drain electrodes 141, 142, 143, and 144, and the first storage electrode 115 and the second storage electrode 116 constituting the storage capacitor Cst are insulated from each other.

The first storage electrode 115 and the second storage electrode 116 may serve as a light-shielding pattern for the second transistor T2.

The first light-shielding pattern 112 is disposed below the first transistor T1 to prevent or suppress the influence of light directed from the lower side of the substrate 111 to the first active layer 113.

The first transistor T1 includes, for example, a first active layer 113, a first gate electrode 114, and first and second source-drain electrodes 141 and 142. As illustrated, the first light-shielding pattern 112 may be connected to one side of the first active layer 113 through the second source-drain electrode 142. In some cases, the first gate electrode 114 of the first transistor T1 may be connected to the first light-shielding pattern 112 through a connection electrode, and thus the first light-shielding pattern 112 can serve as a double gate along with the first gate electrode 114. In this double gate structure, the same or substantially same voltage can be applied to the first light-shielding pattern 112 and the first gate electrode 114.

The first storage electrode 115 and the second storage electrode 116 that overlap each other constitute the storage capacitor Cst having the fifth insulating layer 125 interposed therebetween.

The second transistor T2 includes, for example, a second active layer 137, a second gate electrode 118, a third source-drain electrode 143, and a fourth source-drain electrode 144. For the second transistor T2, the first storage electrode 115 and/or the second storage electrode 116 can serve as a light-shielding pattern.

The second transistor T2 may be connected to the first electrode 161 of the light-emitting element ED through a connection electrode 151.

The illustrated circuit configuration of the subpixel in the first sensor part A (A1 and A2) is an example, and the illustrated transistors and capacitor may be modified, or other transistors and/or capacitors may be added.

In the display device according to an example embodiment of the present disclosure, each wiring layer disposed on the substrate 111, including the first light-shielding pattern 112, may form one layer of the metal blocks. In the display device of the example embodiments of the present disclosure, the first to third metal blocks BLM (BLM1, BLM2, and BLM3) may include electrodes included in transistors in subpixels SP as metal layers. As shown in FIG. 4, the first to third metal blocks (BLM1, BLM2, BLM3) may include metal layers disposed in the same layer as electrode layers included respectively in at least the first and second transistors T1 and T2.

For example, the first metal block BLM1 includes the lower metal layer 114A from the same layer as the first gate electrode 114 or the first storage electrode 115, the first hole CT1 in the fifth to seventh insulating layers 125, 126, and 127 formed in an area overlapping the lower metal layer 114A, and the upper metal layer 118A provided on a portion of the seventh insulating layer 127 and filling the first hole CT1. The upper metal layer 118A may be from the same layer as the second gate electrode 118 of the second transistor T2.

The second metal block BLM2 includes the lower metal layer 118B from the same layer as the second gate electrode 118 of the second transistor T2, the second hole CT2 in the eighth insulating layer 128 overlapping a portion of the lower metal layer 118B, and the upper metal layer 141A provided on a portion of the eighth insulating layer 128 and filling the second hole CT2. Here, the upper metal layer 141A may be made of the same or substantially same metal as the first to fourth source-drain electrodes 141, 142, 143, and 144.

The third metal block BLM4 includes the lower metal layer 141B from the same layer as the first to fourth source-drain electrodes 141, 142, 143, and 144 of the second transistor T2, the third hole CT3 in the first planarization layer 131 overlapping a portion of the lower metal layer 141B, and the upper metal layer 152 provided on a portion of the first planarization layer 131 and filling the third hole CT3. Here, the upper metal layer 152 may be made of the same or substantially same metal as the connection electrode 151 connecting the second transistor T2 and the first electrode 161 of the light-emitting element 160.

In this way, the metal blocks BLM (BLM1, BLM2, and BLM3) include at least two metal layers provided between the substrate 111 and the light-emitting element 160, such as the first and second transistors T1 and T2, the storage capacitor Cst, the first light-shielding pattern 112, and the connection electrode 151, and have vertical paths in the holes CT1, CT2, and CT3 in the insulating layers. When light propagates vertically to the sensor SS, the metal blocks BLM (BLM1, BLM2, and BLM3) prevent or block the light from propagating horizontally or laterally through the transparent materials of the insulating layers 120, 131, and 132 on the substrate 111, thereby preventing or suppressing deterioration of reliability of elements like the transistors T1 and T2 disposed within the sensor SS or around the sensor SS, such as changes in the threshold voltages or mobility characteristics due to light.

The insulating layer 120 provided on the substrate 111 may include, for example, a first insulating layer 121, a second insulating layer 122, a third insulating layer 123, a fourth insulating layer 124, a fifth insulating layer 125, a sixth insulating layer 126, a seventh insulating layer 127, and an eighth insulating layer 128. The insulating layer 120 may include an inorganic insulating material.

The first insulating layer 121 is disposed in the active area AA and the non-active area NA on the substrate 111. The first insulating layer 121 may be a buffer layer and may serve as a buffer layer known in the art. The first insulating layer 121 may be disposed on the substrate 111 to protect structures on the substrate 111 from moisture penetrating through the substrate 111 and to planarize the surface of the substrate 111. The first insulating layer 121 may include a plurality of inorganic insulating layers.

The first insulating layer 121 may extend to the edge of the non-active area NA of the substrate 111 to prevent moisture from penetrating from the edge of the substrate 111. The first insulating layer 121 may be a single inorganic layer or may be composed of a plurality of alternately-laminated inorganic layers.

For example, the first insulating layer 121 may include one or more inorganic layers among a silicon oxide (SiOx) layer, a silicon nitride (SiNx) layer, and a silicon oxynitride (SiOxNy) layer, or may include a laminate thereof.

For example, the first light-shielding pattern 112 may be provided on the first insulating layer 121. For example, the first light-shielding pattern 112 may be made of a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The second insulating layer 122 may be disposed on the first insulating layer 121. The second insulating layer 122 may serve as, for example, a second buffer layer. The transistors provided on the substrate 111 may include a polysilicon type transistors having an active layer made of crystalline silicon. In this case, the second insulating layer 122 may stabilize and planarize the surface on which the active layer including crystalline silicon is formed. The second insulating layer 122 may include an inorganic layer, for example, a silicon oxide (SiOx) layer, a silicon nitride (SiNx) layer, or a laminate thereof.

The third insulating layer 123 serving as a buffer layer of the first active layer 113 may be additionally provided on the second insulating layer 122. The third insulating layer 123 may include an inorganic layer, for example, a silicon oxide (SiOx) layer, a silicon nitride (SiNx) layer, or a laminate thereof.

The first active layer 113 including crystalline silicon may be provided on the third insulating layer 123. The first active layer 113 may be formed of crystalline silicon, for example, by forming amorphous silicon on the entire surface of the third insulating layer 123 and then crystallizing the same through a laser radiation process.

The fourth insulating layer 124 may be provided on the third insulating layer 123 to cover the first active layer 113. The fourth insulating layer 124 may be used as a gate insulating layer of the first transistor T1 including crystalline silicon as the first active layer 113.

The first gate electrode 114 of the first transistor T1, the first storage electrode 115 of the storage capacitor Cst, and the lower metal layer 114A of the first metal block BLM1 may be provided on the fourth insulating layer 124.

The first gate electrode 114, the first storage electrode 115, and the lower metal layer 114A of the first metal block BLM1 may be made of, for example, a light-shielding conductive metal material. Specifically, the light-shielding conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The fifth insulating layer 125 may be disposed on the fourth insulating layer 124 to cover the first gate electrode 114 and the first storage electrode 115. The fifth insulating layer 125 serves as an insulator between the first and second storage electrodes 115 and 116, and may also serve as an interlayer insulating layer of the first transistor T1 including polycrystalline silicon as the first active layer 113.

The fifth insulating layer 125 may include an inorganic material layer. The inorganic material layer may include, for example, a silicon nitride (SiNx) layer or a silicon oxide (SiOx) layer.

The second storage electrode 116 overlapping the first storage electrode 115 may be formed on the fifth insulating layer 125 using a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first storage electrode 115 and the second storage electrode 116 may each be a single layer or may each have a laminated structure of a plurality of different metal materials.

The sixth insulating layer 126 may be disposed on the fifth insulating layer 125 on which the second storage electrode 116 is disposed. The inorganic insulating material of the sixth insulating layer 126 may be used to planarize the surface on which the second transistor T2 is formed. The sixth insulating layer 126 may include a single inorganic insulating layer including a silicon oxide (SiOx) layer or a laminate of other inorganic insulating layers and a silicon oxide layer.

The sixth insulating layer 126 is located below the second active layer 137 and serves as a buffer layer, and may also planarize the surface on which the second active layer 137 is formed. Since the sixth insulating layer 126 does not emit hydrogen particles during a heat treatment process, etc., it is possible to prevent or protect the reliability of the second active layer 137 made of an oxide semiconductor disposed adjacent to the sixth insulating layer 126 from decreasing due to hydrogen particles.

The second active layer 137 of the second transistor T2 may be disposed on the sixth insulating layer 126. The second active layer 137 may include, for example, an oxide semiconductor material. The oxide semiconductor material may be composed of a combination of at least one metal selected from zinc (Zn), indium (In), gallium (Ga), tin (Sn), and titanium (Ti), and an oxide. In some cases, a metal with high conductivity, such as iron (Fe), may be further included in the oxide semiconductor material to increase mobility.

More specifically, examples of the oxide semiconductor material forming the second active layer 137 include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), iron-indium-zinc oxide (FIZO), etc.

The seventh insulating layer 127 may be disposed to cover the second active layer 137. The seventh insulating layer 127 may include a silicon oxide layer or a silicon nitride layer. The seventh insulating layer 127 may serve as a gate insulating layer of the second transistor T2.

The first hole CT1 is formed by sequentially penetrating the seventh insulating layer 127, the sixth insulating layer 126, and the fifth insulating layer 125 to expose at least a portion of the lower metal layer 114A of the first metal block BLM.

A conductive metal material is deposited on the seventh insulating layer 127 to form the second gate electrode 118. A photosensitive resist is applied to the conductive metal material, and then is exposed and developed such that a resist pattern selectively remains in a region where the second gate electrode 118 will be formed, in a region including the area of the first hole CT1, and in a region where the lower metal layer 118B of the second metal block BLM2 will be formed. The conductive metal material is patterned using the resist pattern to form the second gate electrode 118 of the second transistor T2, the upper metal layer 118A of the first metal block BLM1 provided on the seventh insulating layer 127 and filling the first hole CT1, and the lower metal layer 118B of the second metal block BLM2.

Here, the upper metal layer 118A penetrates or fills the first hole CT1 and comes into contact with the lower metal layer 114A. The upper metal layer 118A of the first metal block BLM1 can block light incident laterally from the transmissive area TA in the sensor SS according to the light-shielding property of the conductive metal material.

The conductive metal material forming the second gate electrode 118, the upper metal layer 118A, and the lower metal layer 118B may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), an titanium (Ti).

The upper metal layer 118A of the first metal block BLM1 and the lower metal layer 118B of the second metal block BLM2 may be provided together on the seventh insulating layer 127 on which the second gate electrode 118 is disposed.

The eighth insulating layer 128 is disposed to cover the first metal block BLM1 and the lower metal layer 118B of the second metal block BLM2.

For example, the eighth insulating layer 128 may be formed by laminating a plurality of inorganic insulating layers to maintain interlayer insulation between the second gate electrode 118 and the third and fourth source-drain electrodes 143 and 144 and to planarize the surface on which the third and fourth source-drain electrodes 143 and 144 are formed.

The second hole CT2 penetrating the eighth insulating layer 128 is formed to expose at least a portion of the lower metal layer 118B of the second metal block BLM. In the same process as the process of forming the second hole CT2, the fifth to eighth insulating layers 125, 126, 127, and 128 are selectively removed together on both sides of the first active layer 113 to form holes that expose portions on both sides of the first active layer 113, and at the same time, the seventh and eighth insulating layers 127 and 128 are selectively removed together on both sides of the second active layer 137 to form holes that expose portions on both sides of the second active layer 137. In the same process, a hole penetrating the second to eighth insulating layers 122, 123, 124, 125, 126, 127, and 128 to expose a predetermined portion of the first light-shielding pattern 112 that protrudes laterally more than the first active layer 113 is formed.

A conductive metal material is deposited on the eighth insulating layer 128 to form the first and second source-drain electrodes 141 and 142 of the first transistor T1 and the third and fourth source-drain electrodes 143 and 144 of the second transistor. A photosensitive resist is applied on the conductive metal material, and then is exposed and developed such that a resist pattern is selectively left on regions where the first to fourth source-drain electrodes 141, 142, 143, and 144 will be formed, on a region where the upper metal layer 141A of the second metal block BLM2 will be formed in an area including the second hole CT2, and on a region where the lower metal layer 141B of the third metal block BLM3 will be formed. The conductive metal material is patterned using the resist pattern to form the first to fourth source-drain electrodes 141, 142, 143, and 144, the upper metal layer 141A of the second metal block BLM2, and the lower metal layer 141B of the third metal block BLM3.

Here, the first and second source-drain electrodes 141 and 142 are connected to the portions on both sides of the first active layer 113 through the contact holes formed in the fifth to eighth insulating layers 125, 126, 127, and 128 on both sides of the first active layer 113. In addition, the second source-drain electrode 142 extends to overlap the first light-shielding pattern 112 that protrudes horizontally more than the first active layer 113 and is connected to the first light-shielding pattern 112 through the contact hole formed in the second to eighth insulating layers 122, 123, 124, 125, 126, 127, and 128 to stabilize the potential of the first light-shielding pattern 112.

The third and fourth source-drain electrodes 143 and 144 are connected to the portions on both sides of the second active layer 137 through the contact holes formed in the seventh and eighth insulating layers 127 and 128 on both sides of the second active layer 137. In addition, the third source-drain electrode 143 is connected to the connection electrode 151 formed thereon subsequently, and may be wider than the fourth source-drain electrode 144.

The upper metal layer 141A of the second metal block BLM2 fills the second hole CT2 provided in the eighth insulating layer 128 and is connected to the lower metal layer 118B.

The lower metal layer 141B of the third metal pattern BLM3 may be provided as an island form on the eighth insulating layer 128.

Some metal block may be disposed at the transmissive area TA as shown in FIG. 4. Each pattern of metal block having a vertical structure nearly occupies a plane area. Thus, even when a part of the metal block overlaps the transmissive area, a transmittance of the transmissive area may be maintained.

Thereafter, a planarization layer PLN may be provided on the eighth insulating layer 128 to planarize the surface on which the light-emitting element 160 is to be formed.

For example, the planarization layer PLN may include a first planarization layer 131 and a second planarization layer 132.

The first and second planarization layers 131 and 132 may be made of an organic material. The organic material forming the first and second planarization layers 131 and 132 may include one or more materials from among acrylic resin, phenolic resin, polyimide resin, unsaturated polyester resin, polyamide resin, benzocyclobutene, polyphenylene resin, and polyphenylene sulfide resin. Each of the first and second planarization layers 131 and 132 is thicker than each of the first to eighth insulating layers 121, 122, 123, 124, 125, 126, 127, and 128 and is advantageous for planarization.

After the first planarization layer 131 is formed, a contact hole exposing the third source-drain electrode 143 of the second transistor T2 and the third hole CT3 exposing at least a portion of the lower metal layer 141B of the third metal block BLM3 are formed in the first planarization layer 131.

Through the contact hole exposing the third source-drain electrode 143, the connection electrode 151 provided on the first planarization layer 131 can be connected to the third source-drain electrode 143. The third hole CT3 is filled with the same or substantially same conductive metal material as the connection electrode 151, and the upper metal layer 152 of the third metal block BLM3 is formed.

Here, the upper metal layer 152 of the third metal block BLM3 filled in the third hole CT3 is in contact with the first planarization layer 131 laterally, and the upper metal layer 152 on the first planarization layer 131 is in contact with the second planarization layer 132. Therefore, the third metal block BLM3 includes the third hole CT3 formed in the thick organic insulating layer, and thus can have a longer vertical height than the first and second holes CT1 and CT2 formed in the inorganic insulating layers.

The connection electrode 151 and the upper metal layer 152 of the third metal block BLM3 may be formed as a multilayer made of one selected from the group consisting of molybdenum (Mo), aluminum (Al), chromium (Cr), gold (Au), titanium (Ti), nickel (Ni), neodymium (Nd), and copper (Cu), or an alloy thereof. However, the embodiments of the present disclosure are not limited thereto. In some cases, the connection electrode 151 may be omitted.

The metal blocks BLM may be formed by additionally using metal layers of the first and second transistors T1 and T2, the first light-shielding pattern 112, or the first and second storage electrodes 115 and 116 of the storage capacitor.

If the connection electrode 151 is omitted, the third source-drain electrode 143 may be directly connected to the first electrode 161 of the light-emitting element 160.

The light-emitting element 160 is formed by laminating the first electrode 161, the intermediate layer(s) 162, and the second electrode 163. The first electrode 161 may be independently provided for each subpixel SP and may be separated from the first electrodes 161 in adjacent subpixels.

The first electrode 161 may include, for example, a metal material having high reflectivity or a transparent electrode. For example, the first electrode 161 may be formed in a single-layer structure of a transparent conductive layer, such as ITO (Indium Tin Oxide), IZO (Indium Zinc Oxide), TO (Tin Oxide), or ITZO (Indium Tin Zinc Oxide), a laminated structure of aluminum (Al) and titanium (Ti), a laminated structure (Ti/Al/Ti) of aluminum (Al) and ITO (ITO/Al/ITO), an APC (Ag/Pd/Cu) alloy, and a laminated structure (ITO/APC/ITO) of an APC alloy and ITO, a laminated structure (Ag/MoTi) of silver (Ag) and molybdenum/titanium alloy, or a single-layer structure made of one material selected from silver (Ag), aluminum (Al), molybdenum (Mo), gold (Au), magnesium (Mg), calcium (Ca), and barium (Ba), or two or more alloy materials. Where the first electrode 161 is formed of a single layer of a transparent conductive layer, light from the light-emitting element 160 can pass through the first electrode 161 and be emitted. Where the first electrode 161 includes a reflective electrode, light can be emitted through the second electrode 163 facing the first electrode 161.

The first electrode 161 includes, for example, a reflective electrode and may serve to block light from being incident on the transistors T1 and T2 below the light-emitting element 160. The first electrode 161 may be formed, for example, in a laminated structure of a first transparent electrode, a reflective electrode, and a second transparent electrode. The second transparent electrode, which is the uppermost electrode of the first electrode 161, may lower the barrier for holes to be injected at the interface with the intermediate layer 162 as a dielectric. Here, the first and second transparent electrodes may be transparent oxide electrodes, such as ITO and IZO. The reflective electrode may include silver, a silver alloy such as APC (Ag-Pd-Cu), aluminum, or an aluminum alloy.

In a top emission type light-emitting display device, the second electrode 163 may include a transparent electrode or a reflective-transmissive electrode that is sufficiently thin to allow light transmission through the second electrode 163. The transparent electrode may include, for example, ITO, IZO, etc., and the reflective-transmissive electrode may be made of, for example, one material selected from silver (Ag), aluminum (Al), molybdenum (Mo), gold (Au), magnesium (Mg), ytterbium (Yb), and strontium (Sr), or an alloy of two or more thereof.

The intermediate layer 162 on the first electrode 161 may include a first common layer related to holes of a hole injection layer and a hole transport layer, an emission layer, a hole blocking layer, and a second common layer related to electrons of an electron transport layer and an electron injection layer.

The light-shielding bank 170 is provided to cover the edge of the first electrode 161, and an opening of the light-shielding bank 170 on the first electrode 161 may be defined as an emission area. The light-shielding bank 170 may include a light-shielding organic insulating material and may maintain a certain vertical thickness or more. The light-shielding bank 170 made of a light-shielding organic insulating material may have a vertical thickness of, for example, 1 μm to 5 μm.

A transparent bank 180 may be additionally provided on the light-shielding bank 170 to protect the light-shielding bank 170 and prevent or block infiltration of impurities. The transparent bank 180 may be optionally provided on the light-shielding bank 170 to serve as a spacer.

The spacer may be locally placed on parts of the upper surface of the light-shielding bank 170 rather than on the entire upper surface of the light-shielding bank 170, thereby preventing or protecting the light-shielding bank 170 or the lower structure below the spacer from collapsing when a deposition mask is applied onto the substrate 111 during a deposition process for forming the intermediate layer 162.

The intermediate layer 162 may include a plurality of functional layers along with an emission layer. For example, the intermediate layer 162 may include a hole injection layer, a hole transport layer, an emission layer, an electron transport layer, and an electron injection layer. The intermediate layer 162 may be formed in a tandem structure having a plurality of stacks each including a hole transport layer, an emission layer, and an electron transport layer, and a charge generation layer between stacks. The charge generation layer may include, for example, an n-type charge generation layer and a p-type charge generation layer.

Since the subpixel SP represents an individual color as a component of the light-emitting element 160, the emission layer may be patterned using a deposition mask including an opening corresponding to the emission area for each subpixel and may be disposed in each subpixel SP.

Functional layers other than the emission layer, such as the hole injection layer, the hole transport layer, the electron transport layer, the electron injection layer, and the charge generation layer, are commonly included in the multiple subpixels. In addition, the second electrode 163 may also be provided in common in the multiple subpixels.

The second electrode 163 may be a thin transparent electrode made of ITO or IZO or a reflective-transmissive electrode made of silver, a silver alloy, magnesium, a magnesium alloy, ytterbium (Yb), or an ytterbium alloy.

A capping layer (not shown) may further be formed on the second electrode 163 to protect the second electrode 163 of the light-emitting element 160 and increase the efficiency of light emission upward.

An encapsulation layer 190 is provided on the second electrode 163 to prevent or block moisture penetration into the internal components and protect the internal components from the outside air.

The encapsulation layer 190 may have, for example, a structure in which a first inorganic encapsulation layer 191, an organic encapsulation layer 192, and a second inorganic encapsulation layer 193 are laminated.

A black matrix 201 overlapping the light-shielding bank 170 and a color filter 202 overlapping the opening of the light-shielding bank 170 may be provided on the encapsulation layer 190.

A passivation layer 203 covering the black matrix 201 and the color filter 202 and protecting the upper surface of the display device may be provided.

In the display device of the example embodiments of the present disclosure, the black matrix 201 and the color filter 202 enable color expression of the emission area of each subpixel of the light emitting element, the black matrix 201 has light absorption in the visible spectrum, and the color filter 202 can block light of wavelengths other than a transmission wavelength of a predetermined color. Therefore, even if external light is incident through the passivation layer 203, the light is blocked by the black matrix 201 and light of wavelengths other than wavelengths having selective transmission can be blocked in the area where the color filter 202 is provided. Thus, the amount of light incident on the light-emitting element 160, among external light, can be reduced to achieve both color transmission and external light reflection functions.

The display device of the example embodiments of the present disclosure also includes the light-shielding bank 170 provided around the light-emitting element 160 to block light incident in an oblique direction, among external light, and to effectively prevent or suppress external light reflection from being visible.

In addition, in the display device of the example embodiments of the present disclosure, to effectively collect light for the sensor SS, as in the first sensor part A, the metal blocks BLM (BLM1, BLM2, and BLM3) are provided along the edge of the transmissive area TA in an area where the transmissive area TA is provided. Accordingly, when external light is incident vertically in an area where external light is received, even if there is side light leaking laterally, the metal blocks BLM made of the light-shielding metal material blocks the side light and prevents or blocks light transmitted laterally on the substrate 111 from being transmitted to the transistors T1 and T2, thereby ensuring the stability of the device.

In addition, the metal blocks BLM (BLM1, BLM2, and BLM3) occupy little planar area and have certain thicknesses. Thus, the influence of side leakage light on the substrate 111 can be effectively prevented or suppressed.

The metal blocks BLM (BLM1, BLM2, and BLM3) can contain metals that are effective in capturing hydrogen, such as titanium, tungsten, etc. Therefore, the metal blocks BLM (BLM2, BLM2, and BLM3) can capture hydrogen remaining in the insulating layer 120 on the substrate 111, thereby preventing or protecting the first and second active layers 113 and 137 adjacent to the insulating layer from being affected by hydrogen.

Hereinafter, a metal block in another example shape will be described.

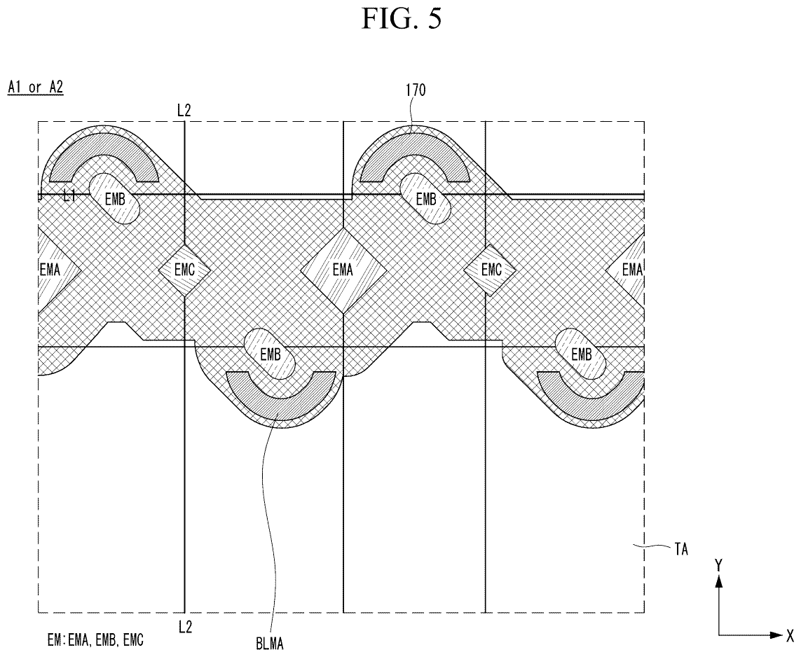

FIG. 5 is a plan view showing the first sensor part A (sensor A1 or A2) in the example display device of FIG. 1 according to a second example embodiment of the present disclosure.

As shown in FIG. 5, the display device according to the second example embodiment of the present disclosure may have a light-shielding bank 170 that protrudes in a curved manner toward a transmissive area TA in some areas along the edges of emission areas EMA, EMB, and EMC of different shapes, and metal blocks BLMA may be provided along the edges of the areas that protrude in a curved manner. In this case, the metal blocks BLMA may be disposed along the curved edges of the light-shielding bank 170 adjacent to the transmissive areas TA.

In the illustrated area, the light-shielding bank 170 positioned outside and adjacent to the second emission areas EMB protrudes in partially curved shapes along the shapes of the edges of the second emission areas EMB. In this case, the metal blocks BLMA may be provided adjacent to the edges of the second emission areas EMB.

Since light reception may be concentrated in the transmissive areas TA, if the metal blocks BLMA are disposed in the areas protruding toward the transmissive areas TA, the metal blocks BLMA adjacent to the transmissive areas TA can effectively block light from spreading or traveling laterally toward the emission areas EM when the first sensor part A (A1 and A2) receives light.

Here, the metal blocks BLMA may overlap the light-shielding bank 170.

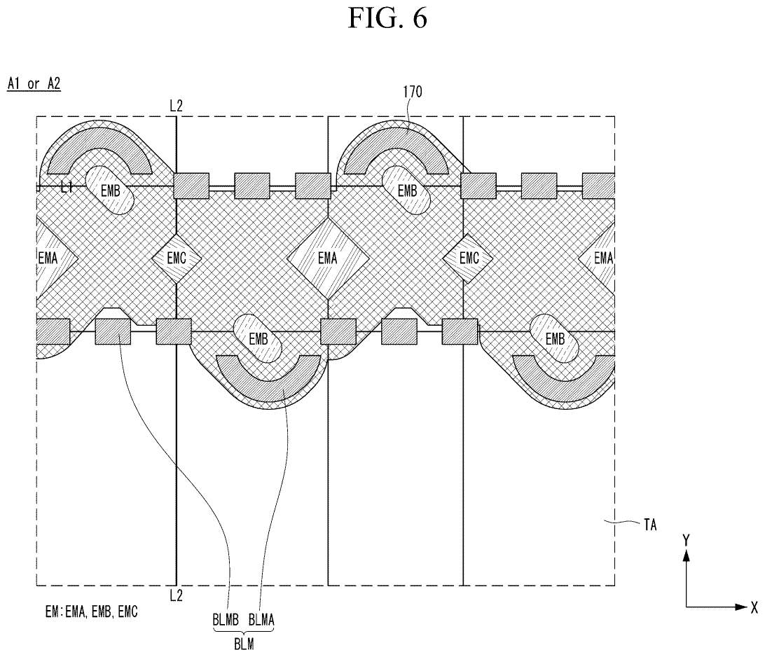

FIG. 6 is a plan view showing a portion of the first sensor part A (sensor A1 or A2) in the example display device of FIG. 1 according to a third example embodiment of the present disclosure.

As shown in FIG. 6, the display device according to the third example embodiment of the present disclosure includes a first group of metal blocks BLMA disposed in a curved shape along the edges of second emission areas EMB and a second group of metal blocks BLM disposed in the row direction.

Here, the first group of metal blocks BLMA may entirely overlap the light-shielding bank 170, and some of the metal blocks BLMB in the second group may overlap the light-shielding bank 170. The second group of metal blocks BLMB has a vertical path of an upper metal layer that fills a hole, which effectively prevents or blocks side or lateral light, and can reduce the non-overlapping area of the light-shielding bank 170 since the metal blocks BLMB have a reduced planar area. Further, the planar area of the metal blocks BLMB in the second group overlaps a first wiring line L1 or a second wiring line L2, and thus the metal blocks BLMB has little influence on the transmittance of the first sensor part A (A1 and A2).

The display devices of the example embodiments of the present disclosure have transmissive areas for improving light reception efficiency in sensor parts, and metal blocks disposed around the transmissive areas. Thus, the transmittance of the transmissive areas can be maintained, and the reliability of elements around the transmissive areas can be improved.

The display devices of the example embodiments of the present disclosure include metal blocks including metal layers of different layers overlapping each other around the sensor part and an upper metal layer filling a hole between the metal layers. Accordingly, when light is vertically incident on the sensor, the metal blocks adjacent to the light propagation path can prevent lateral light transmission, thereby preventing elements, such as transistors, disposed on the substrate from being affected by light reception of the sensor.

The display devices of the example embodiments of the present disclosure can prevent or suppress external light reflection using the light-blocking bank defining emission areas and the black matrix and the color filter array disposed on the encapsulation layer without adding a separate polarizing plate.

The display devices of the example embodiments of the present disclosure have a vertical connection between metal layers provided in different layers, thereby reducing wiring resistance where a metal layer is used as a power voltage line.

In the display devices of the example embodiments of the present disclosure, as transistors having a multi-stack structure are provided in an area overlapping light-emitting elements on the substrate, metal blocks having different vertical lengths can be formed. Thus, the light sensitivity of each transistor having a multi-stack structure can be effectively prevented.

In the display devices of the example embodiments of the present disclosure, the metal blocks can be formed using components of transistors disposed between the substrate and light-emitting elements and the same metal layers as wiring lines. Thus, it is not necessary to change the layer structure of the display device. Accordingly, the production energy for producing the display device can be reduced, and the use of hazardous production materials or regulated substances can be reduced, which is advantageous for recycling and more advantageous for achieving an eco-friendly display device.

Hereinafter, other examples of vertical connection of metal blocks will be described.

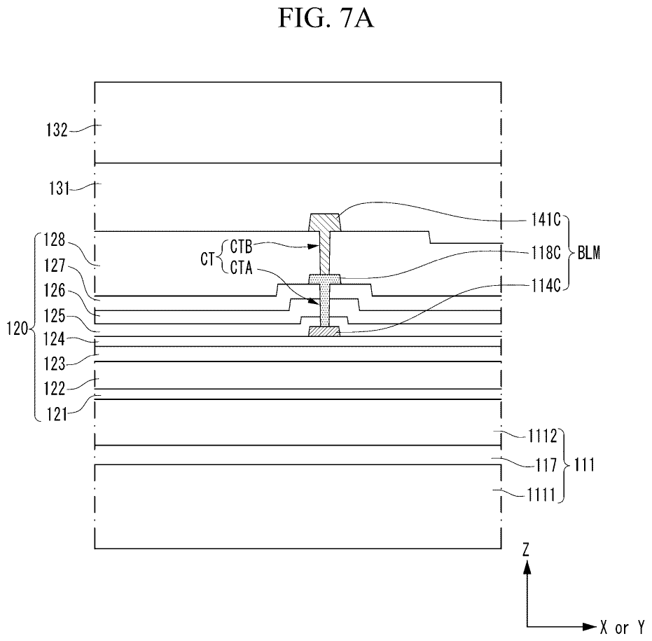

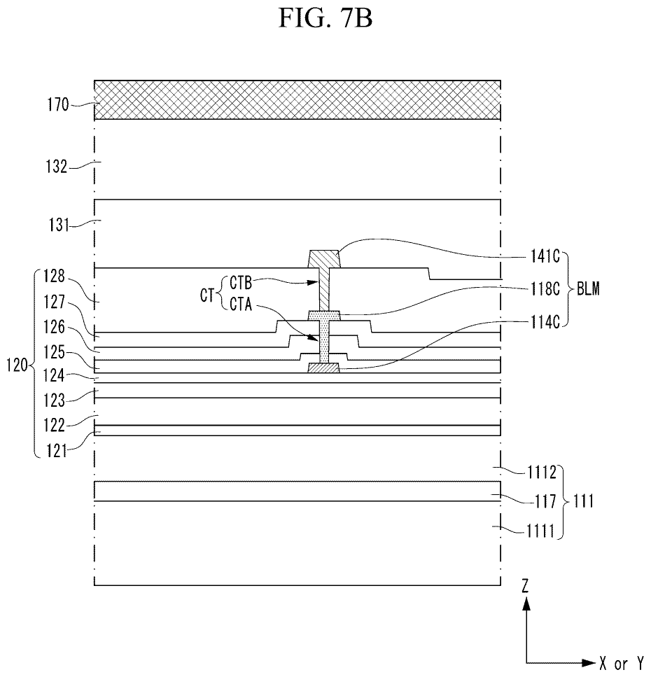

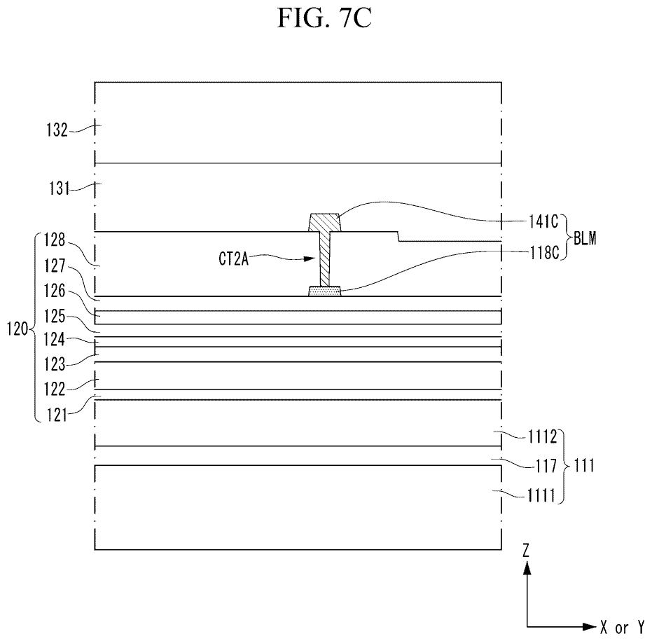

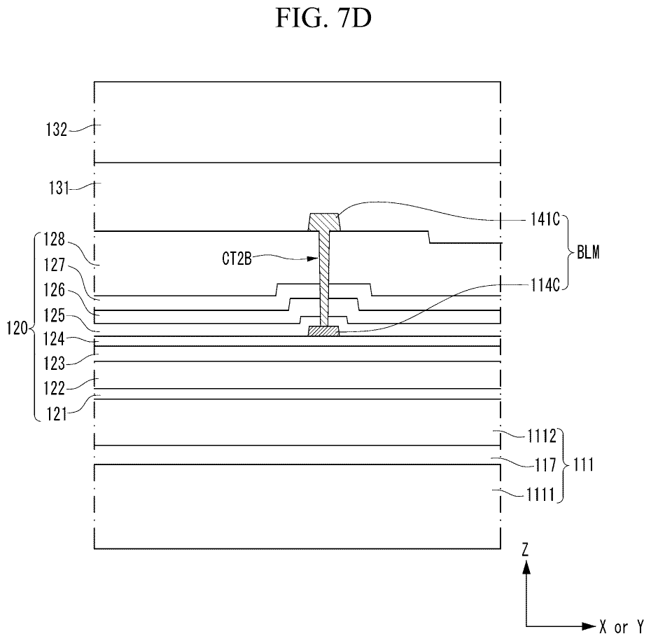

FIGS. 7A to 7D are cross-sectional views showing various example embodiments of a metal block.

The example metal block BLM illustrated in FIG. 7A is formed by including a first metal layer 114C, a second metal layer 118C that fills a first hole CTA penetrating the fifth to seventh insulating layers 125, 126, and 127 and is disposed on the seventh insulating layer 127, and a third metal layer 141C that overlaps the second metal layer 118C and fills a second hole CTB formed in the eighth insulating layer 128. Here, the first metal layer 114C may be from the same layer as the first gate electrode 114 of the first transistor T1. The second metal layer 118C may be from the same layer as the second gate electrode 118 of the second transistor T2. The third metal layer 141C may be from the same layer as the first to fourth source-drain electrodes 141, 142, 143, and 144 of the first and second transistors T1 and T2.

Here, the holes CT of the metal block BLM includes the first hole CTA and the second hole CTB that overlap each other. Since the first hole CTA and the second hole CTB overlap each other, the overall vertical length of the metal block BLM is long. In addition, even if the planar area of the metal block BLM is not increased, lateral light transmission from the sensor area to a non-sensor area can be blocked in the fifth to eighth insulating layers 125, 126, 127, and 128 which are thick.

In another aspect, where a transistor includes an active layer made of an oxide semiconductor material, the off-state characteristics are excellent, but the characteristics of the active layer may be deteriorated due to light transmission. As in the example embodiments of the present disclosure, the metal blocks penetrate the seventh insulating layer 127 and the sixth insulating layer 126 adjacent to the second active layer 137 made of an oxide semiconductor material, and thus the stability of the active layer 137 made of the oxide semiconductor can be secured.

As shown in FIG. 7A, the metal block BLM may be covered by the first and second planarization layers 131 and 132.

The metal block BLM can prevent or block lateral leakage of light traveling through the sensor SS and prevent or suppress the influence of the leaked light on the elements, including the transistors, around the metal block BLM.

As shown in FIG. 7B, the light-shielding bank 170 may be further provided on the first and second planarization layers 131 and 132 in the area where the metal block BLM is disposed. The light-shielding bank 170 may include a material that absorbs light of at least some wavelengths in the visible spectrum. The light-shielding bank 170 may include a black pigment.

The metal block BLM of the example embodiments of the present disclosure serves as a shield for light traveling in a horizontal direction on the substrate 111, and may serve to prevent transmission of side leakage light outside of the light-shielding bank 170 that directly blocks direct light.

An example metal block BLM illustrated in FIG. 7C is formed by including a second metal layer 118C disposed on the seventh insulating layer 127 and a third metal layer 141C that overlaps the second metal layer 118C and fills a hole CT2A formed in the eighth insulating layer 128. In this case, the metal layer of the metal block is formed on the seventh insulating layer 127 adjacent to the active layer 137, and thus the stability of the active layer 137 made of an oxide semiconductor can be secured.

An example metal block BLM illustrated in FIG. 7D is formed by including a first metal layer 114C and a third metal layer 141C that fills a hole CT2B penetrating the fifth to eighth insulating layers 125, 126, 127, and 128 and is formed in the eighth insulating layer 128. Here, the first metal layer 114C may be from the same layer as the first gate electrode 114 of the first transistor T1. The third metal layer 141C may be from the same layer as the first to fourth source-drain electrodes 141, 142, 143, and 144 of the first and second transistors T1 and T2. The metal block BLM having the same vertical length as the metal block BLM illustrated in FIG. 7A described above can be provided using the single hole CT2B having a vertical path.

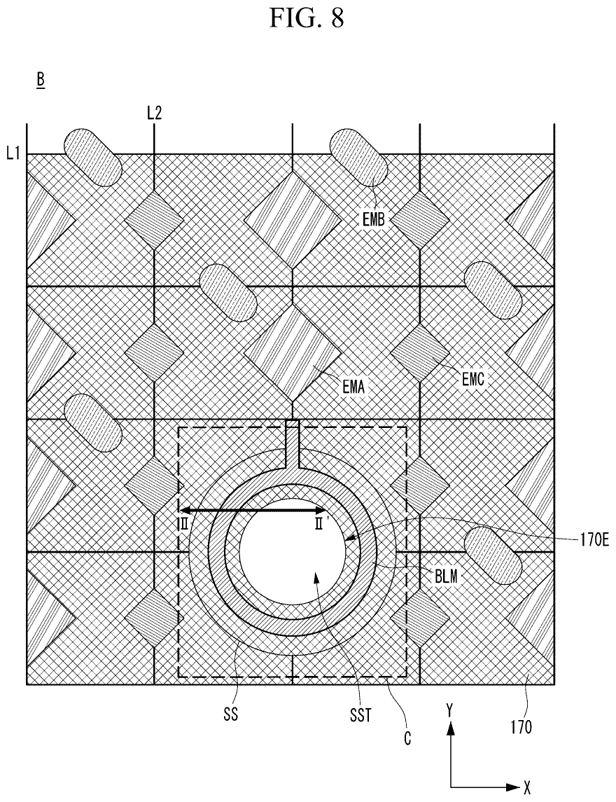

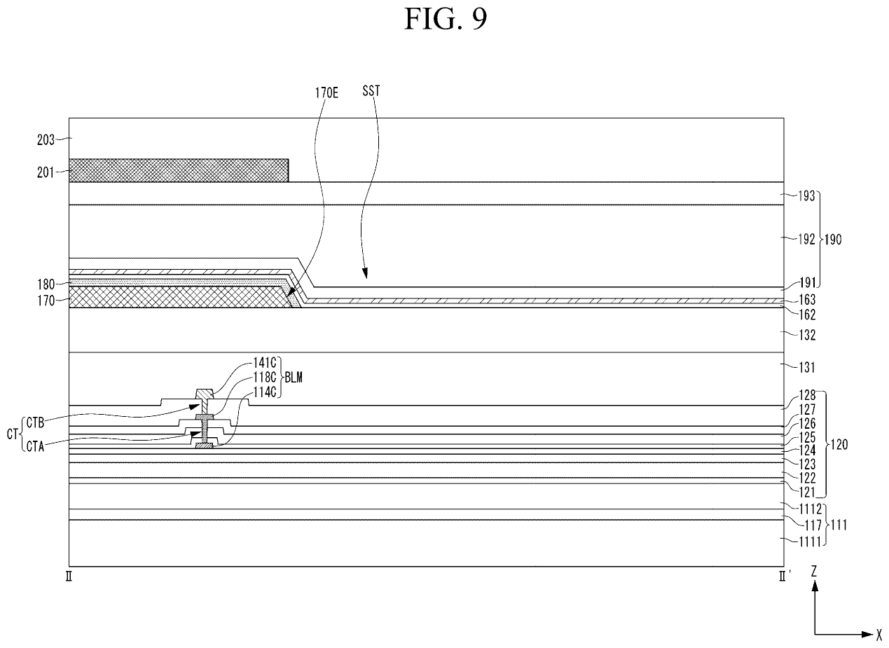

FIG. 8 is a plan view showing a portion of sensor part B in the example display device of FIG. 1 according to a fourth example embodiment of the present disclosure. FIG. 9 is a cross-sectional view taken along line II-II′ in FIG. 8.

FIG. 8 shows the second sensor part B of FIG. 1, which may include an RGB sensor that detects the color concentration of ambient light and/or an illuminance sensor that detects the brightness of ambient light.

As shown in FIG. 8, the second sensor part B detects ambient light in an area where the sensor SS is located and does not directly display an image in that area. Thus, emission areas EMA, EMB, and EMC are regularly disposed around the sensor SS.

The sensor SS may be provided on the lower side of the substrate 111 as shown in FIG. 4. As illustrated in FIG. 9, some metal block BLM may not be overlapped with the sensor SS. A driving chip of the sensor SS may not be provided at a light receiving part SST of the sensor SS.

To increase the transmittance of ambient light, the sensor SS may have an opening of a light-shielding bank 170 defining emission areas EMA, EMB, and EMC on the substrate 111, which has a size of a light receiving part SST of the sensor SS.

In FIG. 8, the light receiving part SST of the sensor is illustrated as a circle, but the embodiments of the present disclosure are not limited thereto. The light receiving part SST may have various other shapes, including an oval shape or a polygonal shape including straight and curved portions.

As shown in FIG. 8 and FIG. 9, the end line 170E of the light-shielding bank 170 is adjacent to the light receiving part SST of the sensor SS, and the light-shielding bank 170 is absent from the light receiving part SST of the sensor SS. The light receiving part SST of the sensor SS includes only transparent layers 120, 131, 132, 162, 163, 190, and 203 from the substrate 111 to the passivation layer 203. Thus, the ambient light coming from above the passivation layer 203 can be sensed on the lower side of the substrate 111 with little to no limitation of transmittance.

The area around the light receiving part SST of the sensor may include the metal blocks BLM at locations overlapping the light-shielding bank 170.

The example metal block BLM illustrated in FIG. 9 is formed by including a first metal layer 114C, a second metal layer 118C that fills a first hole CTA penetrating the fifth to seventh insulating layers 125, 126, and 127 and disposed on the seventh insulating layer 127, and a third metal layer 141C that overlaps the second metal layer 118C and fills a second hole CTB formed in the eighth insulating layer 128. That is, the metal block BLM is formed such that the triple-layer metal layers overlap the first and second holes CTA and CTB to have a long vertical path.

Here, the first metal layer 114C may be from the same layer as the first gate electrode 114 of the first transistor T1. The second metal layer 118C may be from the same layer as the second gate electrode 118 of the second transistor T2. The third metal layer 141C may be from the same layer as the first to fourth source-drain electrodes 141, 142, 143, and 144 of the first and second transistors T1 and T2.

However, the proposed metal block BLM here is an example, and the metal block BLM may be provided in various other shapes, including as shapes divided in a plane, as shown for example in FIG. 3 to FIG. 6. In addition, the metal block BLM may have a vertical structure in which metal layers of a two-layer structure are combined through a hole that penetrates at least one insulating layer, as shown for example in FIG. 4, FIG. 7B, and FIG. 7C.

The metal block BLM is positioned between the sensor and subpixels located around the sensor. When light passes vertically through the light receiving part SST of the sensor SS, the metal block BLM can prevent or block the light from being diffused and transmitted laterally through the insulating layer 120 or the first and second planarization layers 131 and 132 on the substrate 111. Accordingly, it is possible to prevent or block ambient light from affecting the characteristics of the transistors T1 and T2 included in the pixel circuit electrically connected to the light-emitting element 160. Lateral transmission of light due to ambient light can affect transistors including active layers having light sensitivity. In the display devices of the example embodiments of the present disclosure, a plurality of metal layers of the metal block BLM are vertically connected in a hole formed in one or more insulating layers adjacent to the active layers. Thus, lateral transmission of light can be prevented or blocked by the metal layer materials filling the hole.

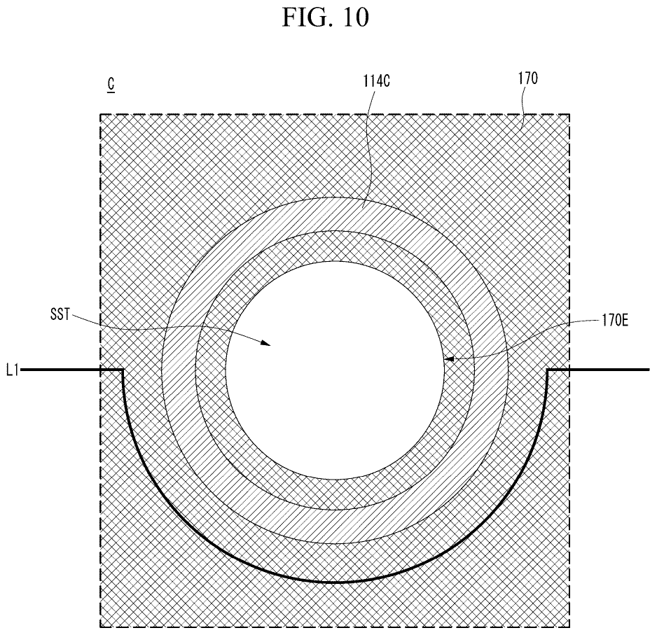

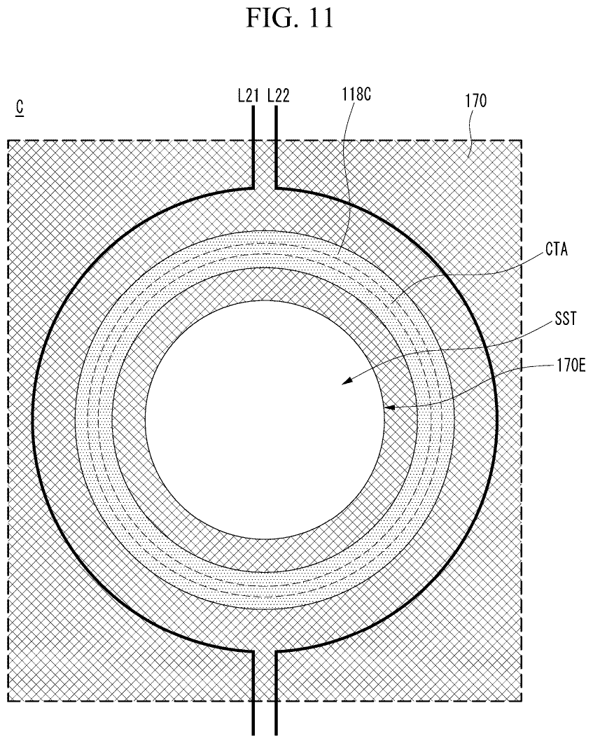

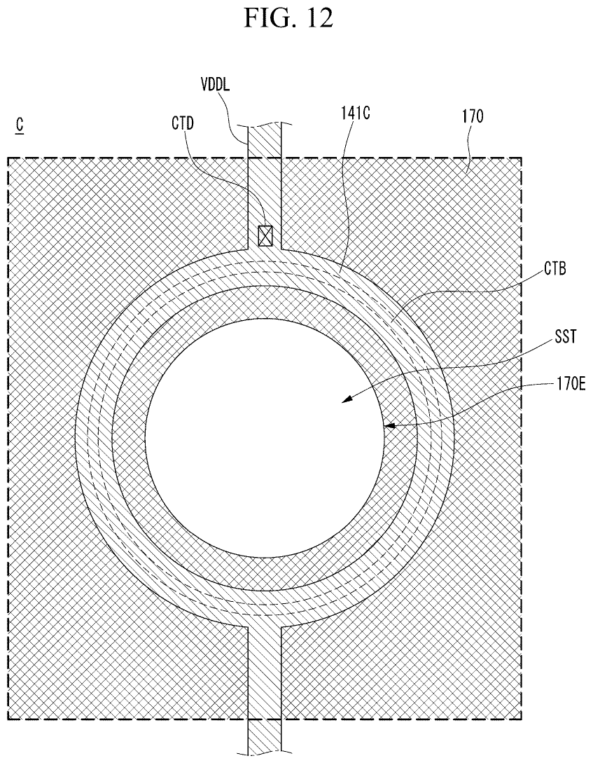

FIG. 10 is a plan view showing an example of the first metal layer 114C in area C of the example display device of FIG. 8. FIG. 11 is a plan view showing an example of the first hole CTA and the second metal layer 118C in area C of the example display device of FIG. 8. FIG. 12 is a plan view showing an example of the second hole CTB and the third metal layer 141C in area C of the example display device of FIG. 8.

As shown in FIG. 10, as an example, the first metal layer 114C may have a circular planar shape surrounding the light receiving part SST of the sensor. The first metal layer 114C may be located, for example, in the same layer as the first wiring line L1 disposed in the X-axis direction of FIG. 8.

Here, the first wiring line L1 may include one or more of gate lines, emission control lines, etc. This is an example, and any wiring line disposed in the X-axis direction may be the first wiring line L1.

The first wiring line L1 may have a curved portion that surrounds the sensor SS so as not to overlap the light receiving part SST, as shown in FIG. 10. This serves to maintain light transmittance relatively high when the light receiving part SST senses ambient light.

As shown in FIG. 11, the second metal layer 118C located on a different layer from the first metal layer 114C may be disposed to fill the first hole CTA as shown in FIG. 9. The first hole CTA is limited to a portion of the planar area of the second metal layer 118C, and a very thin metal line is provided therein when the substrate 111 is observed in a plane.

In addition, second wiring lines L21 and L22 may be disposed in the Y-axis direction of FIG. 8 on the same layer as the second metal layer 118C. The second wiring lines L21 and L22 may include a data line DL, a high-level voltage line VDDL, and a low-level voltage line VSSL described in FIG. 2. This is an example, and any wiring line disposed in the Y-axis direction may be a second wiring line L2.

As shown in FIG. 12, the third metal layer 141C disposed on the second metal layer 118C may be disposed to fill the second hole CTB in the area overlapping the second metal layer 118C as shown in FIG. 9. The second hole CTB is limited to a portion of the planar area of the third metal layer 141C, and a very thin metal line is formed therein when the substrate 111 is observed in a plane.

As shown in FIG. 12, the third metal layer 141C is connected to at least one second wiring line L2 extending upward and downward and disposed in the Y-axis direction, thereby reducing the line resistance of the second wiring line L2. The third metal layer 141C may be wider than the second wiring line L2. The third metal layer 141C may be from the same layer as the source-drain electrodes 141, 142, 143, and 144 of the transistors. The third metal layer 141C, which constitutes a part of the metal block BLM, may connect some of the second wiring lines L2 (L21 and L22), for example, the high-level voltage line VDDL through which the high-level voltage is supplied to an additional contact hole CTD, thereby reducing the line resistance. Accordingly, the line resistance can be reduced without adding a process or adding a material. Here, the illustrated example is merely an example, and the present disclosure is not limited thereto. For example, by changing the position of the additional contact hole CTD, another wiring line to which a different voltage is applied and the third metal layer 141C may be connected, thereby reducing the resistance of the other wiring line.

The high-level voltage line VDDL and the low-level voltage line VSSL through which voltages are applied occupy a relatively large area on the substrate 111 compared to other wiring lines. By connecting at least one of the high-level voltage line VDDL and the low-level voltage line VSSL with at least one metal layer of the metal block BLM, the line resistance can be reduced to effectively prevent or suppress luminance unevenness caused by a resistance difference between regions in the display panel.

As described, in the display device of the example embodiments of the present disclosure, the metal block can be formed by using the same metal layers as components of transistors or wiring lines disposed between the substrate and the light-emitting elements, and thus the layer structure in the display device need not be changed. Therefore, the production energy for producing the display device can be reduced, and the use of hazardous production materials or regulated substances can be reduced, which is advantageous for recycling and more advantageous for achieving an eco-friendly display device.

The display device according to the example embodiments of the present disclosure can reduce a defect rate by preventing deterioration of component reliability, and can achieve ESG (Environmental/Social/Governance) by reducing production energy through process optimization.

The display devices of the example embodiments illustrated in FIG. 8 to FIG. 12 have variations in the area of the substrate 111 overlapping the second sensor part B that detects light.

The metal block BLM formed by laminating the first to third metal layers 114C/118C/141C may have a shape that surrounds the light receiving part SST of the sensor SS without overlapping the light receiving part SST of the sensor SS. In addition, the metal block BLM may overlap with the light-shielding bank 170 that defines the emission areas EMA, EMB, and EMC disposed around the sensor SS to prevent external light from being visible.

The transparent bank 180 may be further provided on the light-shielding bank 170 for protection.

Each of the emission area EMA, EMB, and EMC around the sensor includes the light-emitting element 160 formed by laminating the first electrode 161, the intermediate layer 162, and the second electrode, as shown for example in FIG. 4.

The encapsulation layer 190 may be formed by alternately laminating inorganic encapsulation layers 191 and 193 and organic encapsulation layer 192 on the light-emitting element 160.

The black matrix 201 may be formed on the encapsulation layer 190 in an area corresponding to the light-shielding bank 170. The black matrix 201 may serve to prevent or suppress external light reflection through light absorption together with the light-shielding bank 170. Accordingly, the display device of the example embodiments of the present disclosure can prevent or suppress external light reflection by using the black matrix 201 and the light-shielding bank 170 without a polarization plate.

In another aspect, the color filter (e.g., 202 in FIG. 4) is provided on the encapsulation layer 190 corresponding to each of the emission areas EMA, EMB, EMC, and can prevent external light reflection together with the black matrix 201 and the light-shielding bank 170.

The area shown in FIG. 9 is the light receiving part SST of the sensor and the area around the light receiving part SST, and the color filter 202 may not be disposed in this area for sensing without distortion of light.

The display device of the example embodiments of the present disclosure has a metal block including different metal layers overlapping each other around the sensor and an upper metal layer material filled in a hole between the metal layers. Thus, when light propagates vertically to the sensor, the metal block adjacent to the light propagation path prevents or blocks lateral light transmission, thereby preventing components like transistors and others disposed on the substrate from being affected by light reception of the sensor.

Various example embodiments of the present disclosure can be described as follows.

A display device according to one or more embodiments of the present disclosure may comprise a substrate including an active area and a non-active area outside the active area; a sensor disposed under a portion of the active area of the substrate; a light-emitting element on the active area of the substrate, the light-emitting element including a first electrode, an intermediate layer on the first electrode and including an emission layer, and a second electrode on the intermediate layer; a light-shielding bank on the first electrode and defining an emission area of the light-emitting element; and a metal block extending vertically and positioned between the substrate and the light-emitting element in a cross-sectional view, the metal block being disposed adjacent to the sensor and including two or more metal layers.

In a display device according to one or more embodiments of the present disclosure, the metal block may be in an island form without an electrical connection to any other component on the substrate.

A display device according to one or more embodiments of the present disclosure may further comprise at least one insulating layer between the substrate and the light-emitting element in the cross-sectional view, the at least one insulating layer having a first hole. The two or more metal layers of the metal block may include a first metal layer under the at least one insulating layer and a second metal layer on the at least one insulating layer, and the second metal layer may extend vertically through the first hole and contact the first metal layer.

In a display device according to one or more embodiments of the present disclosure, the at least one insulating layer includes a plurality of different inorganic insulating materials.

A display device according to one or more embodiments of the present disclosure may further comprise a transistor between the substrate and the first electrode of the light-emitting element, and including an oxide semiconductor layer, a gate electrode, and a source or drain electrode. The at least one insulating layer may be disposed between the oxide semiconductor layer and the gate electrode, and at least a portion of the first hole may be adjacent to the oxide semiconductor layer.

A display device according to one or more embodiments of the present disclosure may further comprise another insulating layer between the second metal layer and the light-emitting element in the cross-sectional view, and having a second hole over the second metal layer. The two or more metal layers of the metal block may further include a third metal layer overlapping the second metal layer, the third metal layer extending through the second hole and contacting the second metal layer.

A display device according to one or more embodiments of the present disclosure may further comprise a planarization layer under the light-emitting element and contacting the third metal layer.

A display device according to one or more embodiments of the present disclosure may further comprise a transistor between the substrate and the light-emitting element in the cross-sectional view and electrically connected to the first electrode of the light-emitting element. The two or more metal layers of the metal block may include a first metal layer having a same material from a same layer as an electrode of the transistor.

A display device according to one or more embodiments of the present disclosure may further comprise a connection electrode between the first electrode and the transistor in a cross-sectional view and electrically connecting the electrode of the transistor to the first electrode. The two or more metal layers of the metal block may further include a second metal layer having a same material from a same layer as the connection electrode.

A display device according to one or more embodiments of the present disclosure may further comprise another transistor electrically connected to the transistor and including a first active layer having a crystalline silicon material. The transistor may include a second active layer having an oxide semiconductor material.

In a display device according to one or more embodiments of the present disclosure, the two or more metal layers of the metal block may include at least one layer of a hydrogen-capturing metal.

A display device according to one or more embodiments of the present disclosure may further comprise a plurality of metal blocks, including the metal block, disposed adjacent to the sensor and arranged in a row direction or a column direction in the active area in a plan view.

In a display device according to one or more embodiments of the present disclosure, the portion of the substrate overlapping the sensor may include a plurality of emission areas, including the emission area of the light-emitting element, and a transmissive area. The light-shielding bank may be disposed between the emission areas and between the emission areas and the transmissive area. The metal block may be vertically positioned between the substrate and a portion of the light-shielding bank in the cross-sectional view, the portion of the light-shielding bank overlapping the sensor.

In a display device according to one or more embodiments of the present disclosure, the metal block may be disposed along an edge of the light-shielding bank adjacent to the transmissive area.

A display device according to one or more embodiments of the present disclosure may further comprise an additional metal block arranged along a row or column direction from the metal block. The additional metal block may be disposed at an edge of the transmissive area adjacent to the light-shielding bank without overlapping the light-shielding bank.

In a display device according to one or more embodiments of the present disclosure, the light-shielding bank may be disposed to surround the transmissive area without overlapping the transmissive area in a plan view.

In a display device according to one or more embodiments of the present disclosure, the metal block may have a smaller width than the portion of the light-shielding bank overlapping the sensor in a plan view.

In a display device according to one or more embodiments of the present disclosure, at l east one of the two or more metal layers included in the metal block may be a power voltage line.

In a display device according to one or more embodiments of the present disclosure, the metal block may be in a floating state.

A display device according to one or more embodiments of the present disclosure may further comprise a transparent bank covering the light-shielding bank.

A display device according to one or more embodiments of the present disclosure may further comprise an encapsulation layer covering the light-emitting element and the light-shielding bank; and an external light reflection prevention layer on the encapsulation layer and including a black matrix and a color filter layer. The encapsulation layer may overlap the sensor.

The display device according to one or more embodiments of the present disclosure has at least the following advantages.

The display device according to one or more embodiments of the present disclosure includes a metal block including different metal layers overlapping each other around a sensor and an upper metal layer material filling a hole between the metal layers. Thus, when light propagates vertically to the sensor portion, the metal block adjacent to the light propagation path prevents or blocks lateral light transmission, thereby preventing or protecting components like transistors and others disposed on the substrate from being affected by light reception of the sensor.

The display device according to one or more embodiments of the present disclosure can prevent or suppress external light reflection by using a light-shielding bank defining emission areas and a black matrix and a color filter array disposed on an encapsulation layer without an additional polarizing plate.

The display device according to one or more embodiments of the present disclosure can reduce line resistance by using a metal layer as a power voltage line using a vertical connection between metal layers provided in different layers.

The display device according to one or more embodiments of the present disclosure includes a metal block disposed at the edge of a transmissive area provided to increase light reception efficiency of the sensor, thereby maintaining the transmittance of the transmissive area and improving the reliability of the elements around the transmissive area.

In the display device according to one or more embodiments of the present disclosure, where transistors of a multi-stack structure are provided in an area overlapping a light-emitting element on the substrate, multiple metal blocks having different vertical lengths can effectively prevent or suppress light sensitivity of each transistor of the multi-stack structure.

In the display device according to one or more embodiments of the present disclosure, the metal block can be formed using the same or substantially same metal layers as components of transistors or wiring lines disposed between the substrate and the light-emitting element, and thus the layer structure of the display device need not be changed. Therefore, the production energy for producing the display device can be reduced, and the use of hazardous production materials or regulated substances can be reduced, which is advantageous for recycling and more advantageous for achieving an eco-friendly display device.

The display device according to one or more embodiments of the present disclosure can prevent or suppress the deterioration of the reliability of elements, thereby reducing a defect rate, and can achieve ESG (Environmental/Social/Governance) by reducing production energy through process optimization.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device, comprising:
a substrate including an active area and a non-active area outside the active area;
a sensor disposed under a portion of the active area of the substrate;
a light-emitting element on the active area of the substrate, the light-emitting element including a first electrode, an intermediate layer on the first electrode and including an emission layer, and a second electrode on the intermediate layer;
a light-shielding bank on the first electrode and defining an emission area of the light-emitting element; and
a metal block extending vertically and positioned between the substrate and the light-emitting element in a cross-sectional view, the metal block being disposed adjacent to the sensor and including two or more metal layers.

2. The display device of claim 1, wherein the metal block is in an island form without an electrical connection to any other component on the substrate.

3. The display device of claim 1, further comprising:
at least one insulating layer between the substrate and the light-emitting element in the cross-sectional view, the at least one insulating layer having a first hole,
wherein the two or more metal layers of the metal block include a first metal layer under the at least one insulating layer and a second metal layer on the at least one insulating layer, and the second metal layer extends vertically through the first hole and contacts the first metal layer.

4. The display device of claim 3, wherein the at least one insulating layer includes a plurality of different inorganic insulating materials.

5. The display device of claim 3, further comprising:
a transistor between the substrate and the first electrode of the light-emitting element, and including an oxide semiconductor layer, a gate electrode, and a source or drain electrode,
wherein the at least one insulating layer is disposed between the oxide semiconductor layer and the gate electrode, and
wherein at least a portion of the first hole is adjacent to the oxide semiconductor layer.

6. The display device of claim 3, further comprising:
another insulating layer between the second metal layer and the light-emitting element in the cross-sectional view, and having a second hole over the second metal layer,
wherein the two or more metal layers of the metal block further include a third metal layer overlapping the second metal layer, the third metal layer extending through the second hole and contacting the second metal layer.

7. The display device of claim 6, further comprising:
a planarization layer under the light-emitting element and contacting the third metal layer.

8. The display device of claim 1, further comprising:
a transistor between the substrate and the light-emitting element in the cross-sectional view and electrically connected to the first electrode of the light-emitting element,
wherein the two or more metal layers of the metal block include a first metal layer having a same material from a same layer as an electrode of the transistor.

9. The display device of claim 8, further comprising:
a connection electrode between the first electrode and the transistor in a cross-sectional view and electrically connecting the electrode of the transistor to the first electrode,
wherein the two or more metal layers of the metal block further include a second metal layer having a same material from a same layer as the connection electrode.

10. The display device of claim 8, further comprising:
another transistor electrically connected to the transistor and including a first active layer having a crystalline silicon material,
wherein the transistor includes a second active layer having an oxide semiconductor material.

11. The display device of claim 1, wherein the two or more metal layers of the metal block include at least one layer of a hydrogen-capturing metal.

12. The display device of claim 1, further comprising a plurality of metal blocks, including the metal block, disposed adjacent to the sensor and arranged in a row direction or a column direction in the active area in a plan view.

13. The display device of claim 1, wherein:
the portion of the substrate overlapping the sensor includes a plurality of emission areas, including the emission area of the light-emitting element, and a transmissive area;
the light-shielding bank is disposed between the emission areas and between the emission areas and the transmissive area; and
the metal block is vertically positioned between the substrate and a portion of the light-shielding bank in the cross-sectional view, the portion of the light-shielding bank overlapping the sensor.

14. The display device of claim 13, wherein the metal block is disposed along an edge of the light-shielding bank adjacent to the transmissive area.

15. The display device of claim 13, further comprising an additional metal block arranged along a row or column direction from the metal block,
wherein the additional metal block is disposed at an edge of the transmissive area adjacent to the light-shielding bank without overlap the light-shielding bank.

16. The display device of claim 13, wherein the light-shielding bank is disposed to surround the transmissive area.

17. The display device of claim 13, wherein the metal block has a smaller width than the portion of the light-shielding bank overlapping the sensor in a plan view.

18. The display device of claim 1, wherein at least one of the two or more metal layers included in the metal block is a power voltage line.

19. The display device of claim 1, further comprising a transparent bank covering the light-shielding bank.

20. The display device of claim 1, further comprising:
an encapsulation layer covering the light-emitting element and the light-shielding bank; and
an external light reflection prevention layer on the encapsulation layer and including a black matrix and a color filter layer,
wherein the encapsulation layer overlaps the sensor.
